(19) United States
(12) Patent Application Publication
(10) Pub. No.: US 2021/0066600 A1
(43) Pub. Date: Mar. 4, 2021

(54) MASK AND MASK ASSEMBLY

(71) Applicants: Chengdu BOE Optoelectronics Technology Co., Ltd., Chengdu (CN); BOE Technology Group Co., Ltd., Beijing (CN)

(72) Inventors: Shuai Du, Beijing (CN); Hongqing Feng, Beijing (CN); Yong Zheng, Beijing (CN); Wenbiao Ding, Beijing (CN)

(73) Assignees: Chengdu BOE Optoelectronics Technology Co., Ltd., Chengdu (CN); BOE Technology Group Co., Ltd., Beijing (CN)

(21) Appl. No.: 16/924,512

(22) Filed: Jul. 9, 2020

(30) Foreign Application Priority Data
Aug. 30, 2019 (CN) 201910822447.X

(51) Int. Cl. H01L 51/00; C23C 14/24; C23C 14/04

(52) U.S. Cl. CPC H01L 51/0011; C23C 14/042; C23C 14/24

(57) ABSTRACT

A mask and a mask assembly with the mask are disclosed. The mask includes: a mask pattern region; a non-mask pattern region around the mask pattern region; and two fixing areas disposed opposite to each other in a first direction in the non-mask pattern region and configured to fix the mask. There is a boundary line between the mask pattern region and the non-mask pattern region in the first direction, and an edge, along the boundary line, of the mask pattern region is concave towards an inner side of the mask pattern region in the first direction.

### CROSS-REFERENCE TO RELATED APPLICATION

This application claims priority to Chinese Patent Application No. 201910822447.X filed on Aug. 30, 2019, which is incorporated herein by reference in its entirety.

### TECHNICAL FIELD

Embodiments of the present disclosure generally relate to the field of mask technology, and in particular, to a mask and mask assembly.

### BACKGROUND

An organic light-emitting diode (OLED) usually needs to be fabricated by a vacuum evaporation method with a mask.

### SUMMARY

Embodiments of the present disclosure provide a mask, including: a mask pattern region; a non-mask pattern region around the mask pattern region; and two fixing areas disposed opposite to each other in a first direction in the non-mask pattern region and configured to fix the mask, wherein there is a boundary line between the mask pattern region and the non-mask pattern region in the first direction, and an edge, along the boundary line, of the mask pattern region is concave towards an inner side of the mask pattern region in the first direction.

In embodiments of the present disclosure, the edge of the mask pattern region has an arc shape.

In embodiments of the present disclosure, the edge of the mask pattern region has a curved shape.

In embodiments of the present disclosure, the edge of the mask pattern region has a broken line shape.

In embodiments of the present disclosure, the edge of the mask pattern region includes two straight-line segments extending from a same point towards opposite sides at a same angle with respect to the first direction.

In embodiments of the present disclosure, the edge of the mask pattern region includes a first straight-line segment extending in a second direction perpendicular to the first direction; and two second straight-line segments respectively extending from two ends of the first straight-line segment towards two opposite sides at a same angle with respect to the first direction.

In embodiments of the present disclosure, the edge of the mask pattern region is axially symmetrical about a center line of the mask extending in the first direction.

In embodiments of the present disclosure, the edge of the mask pattern region is axially symmetrical about a straight line extending in the first direction.

In embodiments of the present disclosure, the mask is axially symmetrical about a center line of the mask extending in the first direction.

In embodiments of the present disclosure, the mask has a rectangular shape, a length direction of the mask is the first direction, and the fixing areas are located at two ends of the mask in the length direction, respectively.

In embodiments of the present disclosure, the mask has a rectangular shape, a width direction of the mask is the first direction, and the fixing areas are located at two sides of the mask in the width direction, respectively.

In embodiments of the present disclosure, the mask has a rectangular shape and has two sides opposite to each other in the first direction, and a minimum distance between the edge of the mask pattern region and one, immediately adjacent to the edge, of the two sides of the mask is greater than 200 microns.

In embodiments of the present disclosure, the mask pattern region includes at least one effective mask region, and the at least one effective mask region is axially symmetrical about a center line of the mask extending in a second direction perpendicular to the first direction.

In embodiments of the present disclosure, there are two boundary lines between the mask pattern region and the non-mask pattern region in the first direction, and each of two edges, along the two boundary lines, of the mask pattern region is concave towards the inner side of the mask pattern region in the first direction.

In embodiments of the present disclosure, the mask is axially symmetrical about a center line of the mask extending in a second direction perpendicular to the first direction.

In embodiments of the present disclosure, the two edges of the mask pattern region are axially symmetrical about a center line of the mask extending in a second direction perpendicular to the first direction.

In embodiments of the present disclosure, the two edges of the mask pattern region are axially symmetrical about a straight liner extending in a second direction perpendicular to the first direction.

In embodiments of the present disclosure, the two edges of the mask pattern region are axially symmetrical about a straight line extending in a second direction perpendicular to the first direction, and each of the two edges of the mask pattern region is axially symmetrical about a straight line extending in the first direction.

Embodiments of the present disclosure further provide a mask assembly, including: the above mentioned mask; and a frame including two opposite borders, wherein the two fixing areas of the mask are respectively fixed to the two opposite borders of the frame, and the mask is subjected to a predetermined tension exerted by the two opposite borders of the frame.

### BRIEF DESCRIPTION OF THE DRAWINGS

Other features, objects and advantages of the embodiments of the present disclosure will become more apparent by reading the detailed description of the non-limiting embodiments made in conjunction with the accompanying drawings in which:

FIG. 1 is a schematic diagram showing a structure of a mask in the related art;

FIG. 2 is a schematic diagram showing a structure of a mask according to an embodiment of the present disclosure;

FIG. 3 is a schematic diagram showing forces exerted on a tensioned mask according to an embodiment of the present disclosure;

FIG. 4 is a schematic diagram showing a structure of a mask according to another embodiment of the present disclosure;

FIG. 5 is a schematic diagram showing a structure of a mask according to still another embodiment of the present disclosure;

FIG. 6 is a schematic diagram showing a simulation of a flatness of the mask in the related art;

FIG. 7 is a schematic diagram showing a simulation of a distorted state of the mask in the related art;

FIG. 8 is a schematic diagram showing a simulation of a flatness of a mask according to an embodiment of the present disclosure;

FIG. 9 is a schematic diagram showing a simulation of a distorted state of a mask according to an embodiment of the present disclosure;

FIG. 10 is a schematic diagram showing a structure of a mask according to a further embodiment of the present disclosure; and

FIG. 11 is a schematic diagram showing a structure of a mask assembly according to an embodiment of the present disclosure.

### DETAILED DESCRIPTION

The disclosure will be further described in detail below with reference to the drawings and embodiments. It can be understood that the specific embodiments described herein are only used for explaining the present disclosure, rather than limiting the present disclosure. It should also be noted that, for ease of description, only the parts related to the present disclosure are shown in the drawings.

Unless otherwise defined, the technical or scientific terms used in the present disclosure shall have the usual meanings understood by persons of ordinary skill in the field to which this disclosure pertain. The terms “first”, “second” and similar words used in this disclosure do not indicate any order, quantity or importance, but are only used to distinguish different components. Words such as “include” or “comprise” mean that the element or article appearing before the word covers an element(s) or article(s) listed after the word and its or their equivalents, but do not exclude other elements or articles. Words such as “connect” or “couple” are not limited to specific physical or mechanical connections, whether direct connection or indirect connection. Terms such as “up”, “down”, “left”, “right”, etc. are only used to indicate the relative positional relationship. When the absolute position of the described object is changed, the relative positional relationship may also be changed accordingly.

It should be noted that the embodiments in the present disclosure and the features in the embodiments can be combined with each other unless they conflict.

The present disclosure will be described in detail below with reference to the drawings and in conjunction with the embodiments.

In the manufacturing process of electronic products, masks are often used to form various patterned layers. For example, the mask is often used in a vapor deposition process of an organic light emitting layer of an organic light emitting diode (OLED) display device.

When the mask is used to form a patterned film layer, the mask needs to be tensioned and fixed to a frame. Because the mask has a small thickness, it is easy to generate wrinkles and distortions in the mask, which makes the mask uneven and causes a bad effect of the mask such as a distorted pattern.

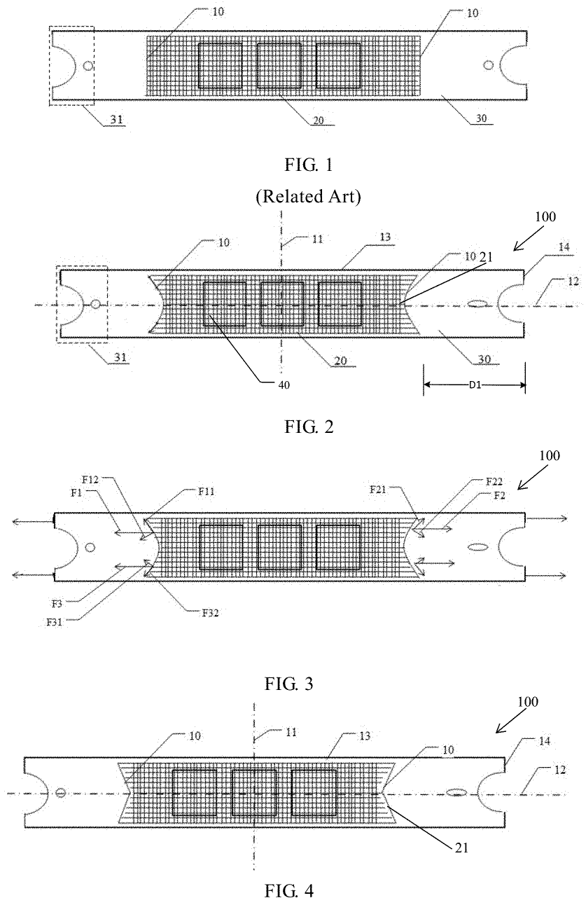

Referring to FIG. 1, a structure of a mask in the related art is shown. The mask includes a mask pattern region 20 and a non-mask pattern region 30 located around the mask pattern region. The non-mask pattern region 30 is provided with fixing areas 31, and the fixing areas 31 are used to fix the mask. A boundary line 10 between the mask pattern region and the non-mask pattern region is a straight line.

In order to solve the above-mentioned unevenness/unflatness problem of the tensioned mask, embodiments of the present disclosure provide a mask with the following structure.

Referring to FIGS. 2 to 5 and 10, embodiments of the present disclosure provide a mask 100. The mask 100 includes: a mask pattern region 20; a non-mask pattern region 30 around the mask pattern region 20; and two fixing areas 31 disposed opposite to each other in a first direction in the non-mask pattern region 30 and configured to fix the mask 100. There is a boundary line 10 between the mask pattern region 20 and the non-mask pattern region 30 in the first direction, and an edge 21 of the mask pattern region 20 along the boundary line 10 is concave towards an inner side of the mask pattern region 20 in the first direction.

In some embodiments, as shown in FIG. 2, the mask includes a mask pattern region 20 and a non-mask pattern region 30 located around the mask pattern region; each of boundary lines 10 between the mask pattern region 20 and the non-mask pattern region 30 is a non-straight line, and the boundary line 10 is concave toward the mask pattern region. The non-mask pattern region 30 is provided with fixing areas 31, which are used to fix the mask, and each of the boundary lines 10 is located opposite to a corresponding one of the fixing areas 31.

A case where the mask is tensioned when the boundary line 10 between the mask pattern region 20 and the non-mask pattern region 30 is a non-straight line will be described as below with reference to FIG. 3. As shown in FIG. 3, the mask is fixed to the frame through the fixing areas, so that the mask is in a tensioned state. In this case, on the non-straight boundary line 10 between the mask pattern region and the non-mask pattern region, a pulling force can have component forces. For example, the pulling force F1 has component forces F11 and F12, thereby reducing wrinkles and distortions and making the mask flat. By comparison, in a mask including a straight boundary line 10, a pulling force has no component force F12 and the mask thus would be wrinkled and distorted.

Referring to FIGS. 2 and 3 and 10, in some embodiments of the present disclosure, the edge 21 of the mask pattern region 20 has an arc shape. In some other embodiments of the present disclosure, the edge 21 of the mask pattern region 20 has a curved shape.

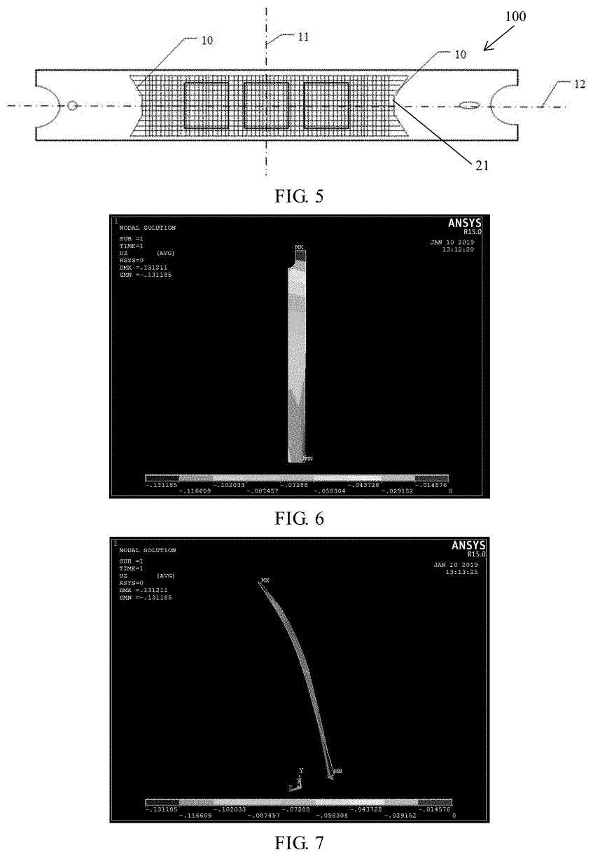

Referring to FIGS. 4 and 5, in some embodiments of the present disclosure, the edge 21 of the mask pattern region 20 has a broken line shape. In the embodiment shown in FIG. 4, the edge 21 of the mask pattern region 20 includes two straight-line segments extending from a same point towards two opposite sides at a same angle with respect to the first direction. In the embodiment shown in FIG. 5, the edge 21 of the mask pattern region 20 includes a first straight-line segment extending in a second direction perpendicular to the first direction, and two second straight-line segments that respectively extend from two ends of the first straight-line segment towards two opposite sides at a same angle with respect to the first direction.

Referring to FIGS. 2 to 5 and 10, in some embodiments of the present disclosure, the mask 100 is axially symmetrical about a center line 12, extending in the first direction, of the mask 100. The edge 21 of the mask pattern region 20 is axially symmetrical about the center line 12 of the mask 100 extending in the first direction. Alternatively, the edge 21 of the mask pattern region 20 is axially symmetrical about a straight line extending in the first direction. That is, the center line of the edge 21 of the mask pattern region 20 extending in the first direction does not coincide with the center line 12 of the mask 100 extending in the first direction.

Referring to FIGS. 2 to 5, in some embodiments of the present disclosure, the mask 100 has a rectangular shape, a length/longitudinal direction of the mask 100 is the first direction, and the fixing areas 31 are located at two ends, in the length direction, of the mask 100, respectively.

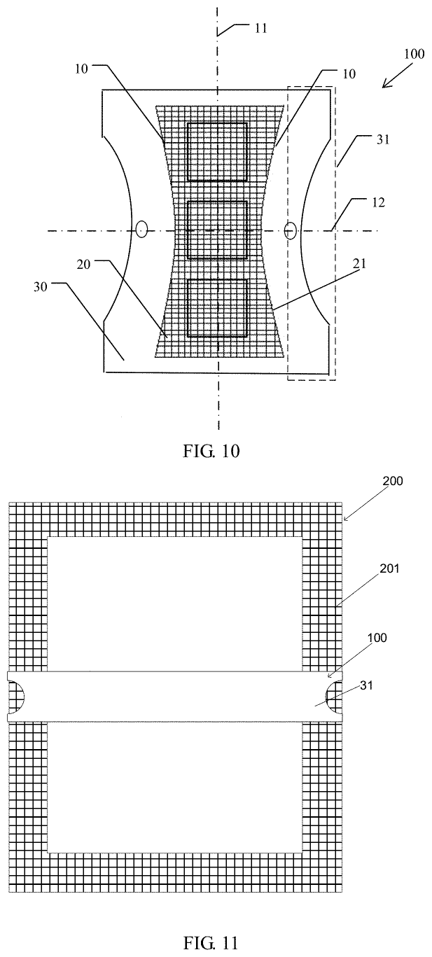

Referring to FIG. 10, in some embodiments of the present disclosure, the mask 100 has a rectangular shape, a width direction of the mask 100 is the first direction, and the fixing areas 31 are located at two ends, in the width direction, of the mask 100, respectively.

Referring to FIG. 2, in some embodiments of the present disclosure, the mask 100 has a rectangular shape, and has two sides 14 opposed to each other in the first direction. A minimum distance D1 between the edge 21 of the mask pattern region 20 and one, immediately adjacent to the edge 21, of the two sides 14 of the mask 100 is greater than 200 microns.

Referring to FIGS. 2 to 5 and 10, in some embodiments of the present disclosure, the mask pattern region 20 includes at least one effective mask region 40, and the at least one effective mask region 40 is axially symmetrical about a center line 11, extending in the second direction perpendicular to the first direction, of the mask 100.

Referring to FIGS. 2 to 5 and 10, in some embodiments of the present disclosure, there are two boundary lines 10 between the mask pattern region 20 and the non-mask pattern region 30 in the first direction. Each of the two edges 21 of the mask pattern region 20 along the two boundary lines 10 is concave towards the inner side of the mask pattern region 20 in the first direction.

Referring to FIGS. 2 to 5 and 10, in some embodiments of the present disclosure, the mask 100 is axially symmetrical about the center line 11 of the mask 100 extending in the second direction perpendicular to the first direction. The two edges 21 of the mask pattern region 20 are axially symmetrical about the center line 11 of the mask 100 extending in the second direction perpendicular to the first direction. Alternatively, the two edges 21 of the mask pattern region 20 are axially symmetrical about a straight line extending in the second direction perpendicular to the first direction. That is, the axis of symmetry of the two edges 21 of the mask pattern region 20 extending in the second direction does not coincide with the center line 11 of the mask 100 extending in the second direction.

Referring to FIGS. 2 to 5 and 10, in some embodiments of the present disclosure, the two edges 21 of the mask pattern region 20 are axially symmetrical about a straight line extending in the second direction perpendicular to the first direction, and each of the two edges 21 of the mask pattern region 20 is axially symmetrical about a straight line extending in the first direction.

The boundary line may have an arc shape or a broken line shape. As shown in FIG. 2, the boundary lines may be arc-shaped; as shown in FIG. 4, the boundary lines may be in a shape of “<”; as shown in FIG. 5, the boundary lines may be in a shape of “(”. In this case, on the non-straight boundary line 10 between the mask pattern region and the non-mask pattern region, the pulling force can have the component force F12, thereby reducing the generation of wrinkles and twists and making the mask flat. The broken line shape in the embodiments of the present disclosure is not limited to those described above, and other boundary lines may also be adopted.

According to some embodiments of the present disclosure, as shown in FIG. 2, the mask is rectangular, and has a long side 13 and a short side 14. The fixing areas 31 are located at two ends, in the length direction, of the mask, and the center line 11, extending in the width direction, of the mask is an axis of symmetry of the boundary lines 10. The fixing areas 31 are disposed at two ends, in the length direction, of the mask, respectively, and the boundary lines 10 that are respectively opposite to the fixing areas 31 and axially symmetrical about the center line 11 of the mask 10 as an axis of symmetry of the boundary lines 10. With the configuration, upon tensioned, pulling forces that are equal in magnitude and opposite in direction, such as pulling forces F1 and F2 as shown in FIG. 3, are obtained at axially symmetrical points about the axis of symmetry of the mask, which is beneficial to the flattening of the mask.

According to some embodiments of the present disclosure, each boundary line 10 itself is axially symmetrical about the center line 12 (as an axis of symmetry) of the mask extending in the length direction. The boundary line 10 is symmetrical about the center line 12 of the mask as the axis of symmetry, so that after the mask is tensioned, the component forces that are equal in magnitude, such as the component forces F11 and F32 in FIG. 3, are generated at the symmetrical points about the axis of symmetry, which is beneficial to the flattening of the mask.

Similarly, the boundary lines 10 on both sides in FIG. 4 and FIG. 5 may also be designed to be symmetrical about the center line 11 as the axis of symmetry, and the boundary lines 10 themselves may be symmetrical about the center line 12 as the axis of symmetry.

According to some embodiments of the present disclosure, a minimum distance D1 between the points of each boundary line 10 and the short side 14 immediately adjacent to the each boundary line 10 is greater than 200 microns. As shown in FIG. 2, the minimum distance between the points of one boundary line 10 and the short side 14 immediately adjacent to the one boundary line 10 is D1, and the minimum distance D1 is greater than 200 microns. If the minimum distance D1 is too small, for example, less than 200 microns, uniformity of a thickness of a film that is deposited with the mask pattern region 20 cannot be guaranteed.

According to some embodiments of the present disclosure, the mask pattern region 20 includes at least one effective mask region 40, and the center line 11 of the mask is an axis of symmetry of the effective mask region 40. As shown in FIG. 2, the mask pattern region 20 includes three effective mask regions 40. The effective mask regions have a symmetrical structure with the center line 11 of the mask as the axis of symmetry. With the symmetrical structure, the effective masking region 40 has a better flattening effect when tensioned.

FIGS. 6-9 are simulation diagrams illustrating the degrees of wrinkling and twisting of the two masks which have a straight boundary line 10 and an arc-shaped boundary line 10, respectively. The two masks have the same size, and the same pulling force is exerted on the fixing areas of the two masks. FIGS. 6-9 show a strain distribution of one-fourth mask, that is, strain is used to indicate the degree of deformation. In FIGS. 6-9, an upper part is strain distribution of the fixing area of the mask, and a lower part is strain distribution of the mask pattern region. An object will be deformed under the action of external force, and the degree of deformation is called a strain. For ease of observation, the lower horizontal bar in the FIGS. 6-9 indicates different intervals for different strains, and each strain value corresponds to a sub-interval. As shown in FIG. 6, the strain of the mask in the range of −0.014576 to −0.131185 includes nine sub-intervals, which correspond to the strains from the upper portion to the lower portion of the mask and reflect change of the strains from the upper portion to the lower portion of the mask. The sub-interval of the strain for the lowest portion of the mask is a sub-interval in which the strain value is −0.131185, and the sub-interval of the strain for the uppermost portion of the mask is a sub-interval in which the strain value is −0.014576.

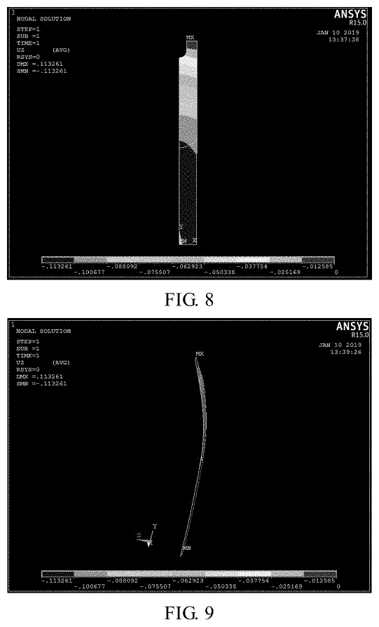

FIGS. 6 and 8 are the simulation diagrams of the flatness of the masks. As shown in FIG. 6, a depression appears near the strain point of −0.116609, which indicates that wrinkles or distortions occur. As shown in FIG. 7, significant distortion appears near the strain point of −0.116609. By comparison, each stress point of the mask in FIG. 8 is smooth, without uneven wrinkles or distortion. As shown in

FIG. 9, no distortion occurs. In addition, the lowest strain interval of −0.113261 in FIG. 8 is significantly larger than the lowest strain interval of −0.116609 in FIG. 6, that is, the flatness in the mask pattern region by illustrated in FIG. 8 is better than that in FIG. 6. It can be seen that after the improvements of the present disclosure, the flatness of the mask has been improved.

In some embodiments of the present disclosure in which the mask is rectangular, as shown in FIG. 10, the fixing areas 31 may also be located at both ends in the width direction of the mask, and the center line 11 of the mask extending in the length direction is the axis of symmetry of the boundary lines. In FIG. 10, the boundary lines 10 are arc-shaped. As for the structure as shown in FIG. 10, the boundary lines 10 may also be in a broken line shape, such as a shape of “<” or a shape of “(”. The broken line shape in the embodiments of the present disclosure is not limited to those, and may be other shapes.

According to some embodiments of the present disclosure, each boundary line 10 itself is axially symmetric about the center line 12 (as the axis of symmetry) extending along the length direction of the mask.

According to some embodiments of the present disclosure, a minimum distance D2 between the points of each of the boundary lines 10 and the long side of the mask immediately adjacent thereto is greater than 200 microns.

Referring to FIGS. 2 to 5 and 10 to 11, embodiments of the present disclosure also provide a mask assembly, the mask assembly includes: the mask 100 described in any of the above embodiments; and a frame 200. The frame 200 includes two borders 201 opposite to each other, and two fixing areas 31 of the mask 100 are respectively fixed to the two opposite borders 201 of the frame 200, such that the mask 100 is subjected to a predetermined tension applied by the two opposite borders 201 of the frame 200.

According to the mask and the mask assembly provided by the embodiments of the present disclosure, the problem that the conventional mask is prone to wrinkle, bend or twist can be solved by setting the boundary lines between the mask pattern region and the non-mask pattern region as non-straight-line boundary lines, and disposing them at positions facing towards the fixing areas respectively. Further, according to some embodiments of the present disclosure, uniform stress in a tensioned mask and an improved flatness of a tensioned mask can be obtained by configuring the boundary lines to be symmetric.

Although some exemplary embodiments of the present disclosure have been described and shown above, those skilled in the art would understand that changes can be made to these exemplary embodiments without departing from the principles and spirit of the present disclosure. The scope of the present disclosure is defined by the claims and their equivalents.

What is claimed is:

1. A mask, comprising:
a mask pattern region;
a non-mask pattern region around the mask pattern region; and
two fixing areas disposed opposite to each other in a first direction in the non-mask pattern region and configured to fix the mask,
wherein there is a boundary line between the mask pattern region and the non-mask pattern region in the first direction, and an edge, along the boundary line, of the mask pattern region is concave towards an inner side of the mask pattern region in the first direction.

2. The mask according to claim 1, wherein:
the edge of the mask pattern region has an arc shape.

3. The mask according to claim 1, wherein:
the edge of the mask pattern region has a curved shape.

4. The mask according to claim 1, wherein:
the edge of the mask pattern region has a broken line shape.

5. The mask according to claim 4, wherein:
the edge of the mask pattern region comprises two straight-line segments extending from a same point towards two opposite sides at a same angle with respect to the first direction.

6. The mask according to claim 4, wherein:
the edge of the mask pattern region comprises a first straight-line segment extending in a second direction perpendicular to the first direction; and two second straight-line segments respectively extending from two ends of the first straight-line segment towards two opposite sides at a same angle with respect to the first direction.

7. The mask according to claim 1, wherein:
the edge of the mask pattern region is axially symmetrical about a center line of the mask extending in the first direction.

8. The mask according to claim 1, wherein:
the edge of the mask pattern region is axially symmetrical about a straight line extending in the first direction.

9. The mask according to claim 1, wherein:
the mask is axially symmetrical about a center line of the mask extending in the first direction.

10. The mask according to claim 1, wherein:
the mask has a rectangular shape, a length direction of the mask is the first direction, and the fixing areas are located at two ends of the mask in the length direction, respectively.

11. The mask according to claim 1, wherein:
the mask has a rectangular shape, a width direction of the mask is the first direction, and the fixing areas are located at two sides of the mask in the width direction, respectively.

12. The mask according to claim 1, wherein:
the mask has a rectangular shape and has two sides opposite to each other in the first direction, and a minimum distance between the edge of the mask pattern region and one, immediately adjacent to the edge, of the two sides of the mask is greater than 200 microns.

13. The mask according to claim 1, wherein:
the mask pattern region comprises at least one effective mask region, and the at least one effective mask region is axially symmetrical about a center line of the mask extending in a second direction perpendicular to the first direction.

14. The mask according to claim 1, wherein:
there are two boundary lines between the mask pattern region and the non-mask pattern region in the first direction, and each of two edges, along the two boundary lines, of the mask pattern region is concave towards the inner side of the mask pattern region in the first direction.

15. The mask according to claim 14, wherein:
the mask is axially symmetrical about a center line of the mask extending in a second direction perpendicular to the first direction.

16. The mask according to claim 14, wherein:
the two edges of the mask pattern region are axially symmetrical about a center line of the mask extending in a second direction perpendicular to the first direction.

17. The mask according to claim 14, wherein:
the two edges of the mask pattern region are axially symmetrical about a straight liner extending in a second direction perpendicular to the first direction.

18. The mask according to claim 14, wherein:
the two edges of the mask pattern region are axially symmetrical about a straight line extending in a second direction perpendicular to the first direction, and each of the two edges of the mask pattern region is axially symmetrical about a straight line extending in the first direction.

19. A mask assembly, comprising:
the mask according to claim 1; and
a frame comprising two opposite borders, wherein the two fixing areas of the mask are respectively fixed to the two opposite borders of the frame, and the mask is subjected to a predetermined tension exerted by the two opposite borders of the frame.
